(19) United States
(12) Patent Application Publication
(10) Pub. No.: US 2025/0140551 A1
(43) Pub. Date: May 1, 2025

(54) METHOD OF FORMING A MEMORY DEVICE IN A RECESSED FEATURE

(71) Applicant: Tokyo Electron Limited, Tokyo (JP)

(72) Inventors: Dina H. Triyoso, Albany, NY (US); Ryota Yonezawa, Albany, NY (US); Robert D. Clark, Leuven (BE)

(21) Appl. No.: 18/816,978

(22) Filed: Aug. 27, 2024

Related U.S. Application Data
(60) Provisional application No. 63/546,141, filed on Oct. 27, 2023.

(51) Int. Cl. H01L 21/02; H10B 53/30

(52) U.S. Cl. CPC H01L 21/0228; H01L 21/02403; H01L 21/02472; H01L 21/02592; H10B 53/30

(57) ABSTRACT

A method of forming a memory device on a substrate includes depositing a first electrode layer within a recessed feature of the substrate using a first atomic layer deposition process, and depositing an amorphous transition metal oxide layer over the first electrode layer using a second atomic layer deposition process at a first substrate temperature. And the method further includes, while maintaining an amorphous state of the amorphous transition metal oxide layer, depositing a second electrode layer over the amorphous transition metal oxide layer using a third atomic layer deposition process at a second substrate temperature, the second substrate temperature being lower than a recrystallization temperature of an amorphous transition metal oxide material of the amorphous transition metal oxide layer, and the first electrode layer, the amorphous transition metal oxide layer, and the second electrode layer forming a memory layer stack.

### CROSS-REFERENCE TO RELATED APPLICATIONS

This application claims the benefit of U.S. Provisional Application No. 63/546,141, filed on Oct. 27, 2023, which application is hereby incorporated herein by reference.

### TECHNICAL FIELD

The present invention relates to semiconductor processing and semiconductor devices, and more particularly, to methods of forming a memory device in recessed features.

### BACKGROUND

In the semiconductor industry, the integration of non-volatile memory technologies, sensor technologies, transmitter technologies, electronic filter technologies, receiver technologies, and the like may be useful for various types of devices and applications. According to various aspects, an electronic device, e.g., a non-volatile memory may be integrated on a chip. A desire for film stacks containing dielectric materials that are ferroelectric (FE) and anti-ferroelectric (AFE) includes good control over the crystallographic phases in advanced 3D structures.

### SUMMARY

In accordance with an embodiment of this disclosure, a method of forming a memory device on a substrate includes depositing a first electrode layer within a recessed feature of the substrate using a first atomic layer deposition process, and depositing an amorphous transition metal oxide layer over the first electrode layer using a second atomic layer deposition process at a first substrate temperature. And the method further includes, while maintaining an amorphous state of the amorphous transition metal oxide layer, depositing a second electrode layer over the amorphous transition metal oxide layer using a third atomic layer deposition process at a second substrate temperature, the second substrate temperature being lower than a recrystallization temperature of an amorphous transition metal oxide material of the amorphous transition metal oxide layer, and the first electrode layer, the amorphous transition metal oxide layer, and the second electrode layer forming a memory layer stack.

In accordance with another embodiment of this disclosure, a method of forming a memory device on a substrate includes loading the substrate into a first atomic layer deposition (ALD) chamber of a ALD system, and performing a first ALD process including flowing a first metal precursor gas to deposit a first electrode layer within a high aspect ratio opening of the substrate. The method further includes loading the substrate into a second ALD chamber of the ALD system, and performing a second ALD process including flowing a gas mixture including tetrakis(ethylmethylamino) hafnium (TEMAHf), tetrakis(ethylmethylamino) zirconium (TEMAZr), and oxidants to deposit an amorphous transition metal oxide layer over the first electrode layer. And the method further includes loading the substrate into a third atomic layer deposition (ALD) chamber of the ALD system and maintaining the substrate at a temperature below an amorphous-to-crystalline temperature of the amorphous transition metal oxide layer, and performing, while maintaining the substrate at the temperature, a third ALD process including flowing a second metal precursor gas to deposit a second electrode layer, the first electrode layer, the amorphous transition metal oxide layer, and the second electrode layer forming a memory layer stack.

And in accordance with yet another embodiment of this disclosure, a method of forming a memory device on a substrate includes depositing a first electrode layer within a recessed feature of the substrate using a first atomic layer deposition process, and depositing an amorphous transition metal oxide layer over the first electrode layer using a second atomic layer deposition process at a first substrate temperature. The method further includes depositing a second electrode layer over the amorphous transition metal oxide layer using a third atomic layer deposition process at a second substrate temperature. And the method further includes annealing the substrate at a third substrate temperature to crystallize the amorphous transition metal oxide layer and form a crystalline transition metal oxide layer, the crystalline transition metal oxide layer having a ferroelectric crystalline phase or an anti-ferroelectric crystalline phase.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1D are cross-sectional views of a structure illustrating various steps of a method of forming a memory device in a high aspect ratio feature in accordance with an embodiment of this disclosure;

FIG. 2 is a cross-sectional view of a structure illustrating an annealing step in accordance with an embodiment of this disclosure;

FIG. 3 is a schematic diagram of an atomic layer deposition (ALD) system in accordance with an embodiment of this disclosure;

FIG. 4 is a plot illustrating X-ray diffraction (XRD) results for a hafnium zirconium oxide (HZO) film deposited using an ALD process at a high temperature in accordance with an embodiment of this disclosure;

FIG. 5 is a plot illustrating XRD results for a HZO film deposited using an ALD process at a low temperature in accordance with an embodiment of this disclosure;

FIG. 6 is a flowchart of a method of forming a memory device in a high aspect ratio feature in accordance with an embodiment of this disclosure;

FIG. 7 is a flowchart of a method of forming a memory device in a high aspect ratio feature in accordance with an embodiment of this disclosure; and

FIG. 8 is a flowchart of a method of forming a memory device in a high aspect ratio feature in accordance with an embodiment of this disclosure.

### DETAILED DESCRIPTION OF ILLUSTRATIVE EMBODIMENTS

The formation of ferroelectric (FE) and anti-ferroelectric (AFE) films in deep aspect ratio structures presents difficulties in semiconductor manufacturing. Current processes using atomic layer deposition (ALD) of titanium nitride (TiN) at 430° C. as a capping layer result in undesirable premature crystallization of hafnium zirconium oxide (HZO) layers (or other amorphous transition metal oxide layers). This premature crystallization hinders the fabrication of optimal ferroelectric characteristics in high aspect ratio features. Additionally, controlling the oxygen content of the TiN layer (or other electrode layers) is beneficial for maximizing ferroelectric properties.

This disclosure presents a method of forming a memory device in high aspect ratio features, which enables stable and controllable ferroelectric properties in transition metal oxide layers of the memory device. The embodiment methods described throughout this disclosure employ a sequence of low-temperature ALD processes integrated into the ferroelectric stack formation. As a result of the low-temperatures used in the ALD processes, the method of this disclosure prevents the premature crystallization of amorphous transition metal oxide layers of the memory device (such as a memory capacitor). The low-temperature ALD process is useful for preventing premature crystallization of the amorphous transition metal oxide layer, maintaining it in an amorphous state until the intended annealing step. Further, a second electrode layer may be engineered to contain approximately 20% oxygen, which is beneficial for achieving maximum ferroelectric characteristics. This all-ALD at low-temperature approach enables the formation of ferroelectric and anti-ferroelectric films in high aspect ratio structures.

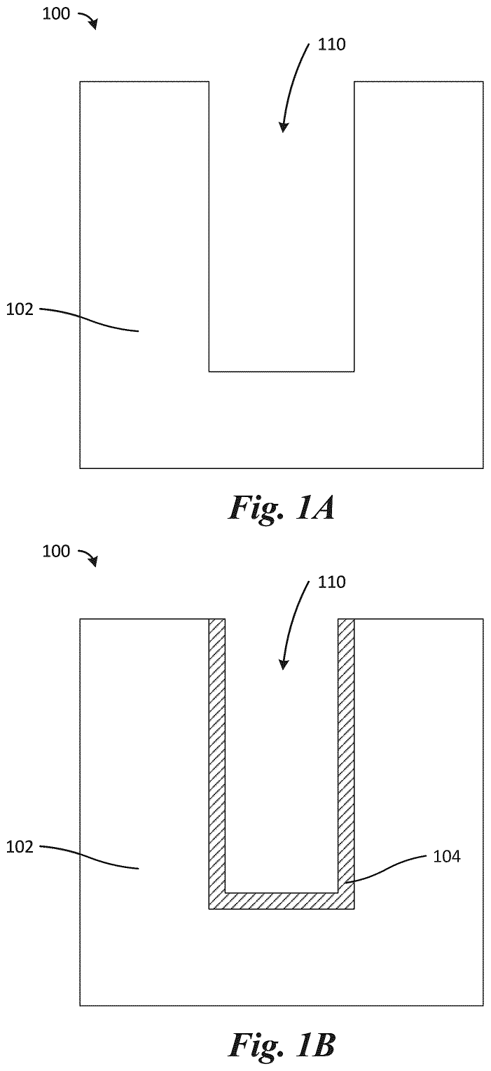

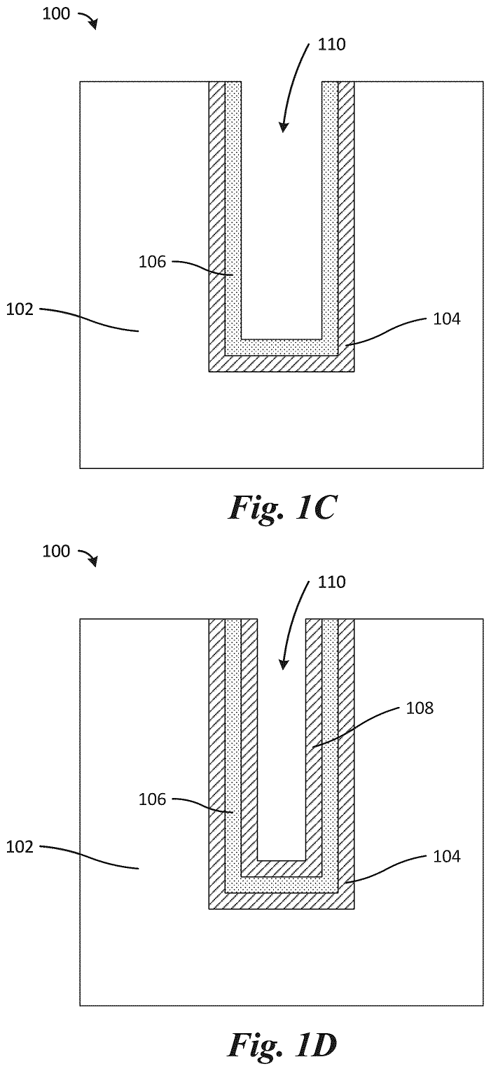

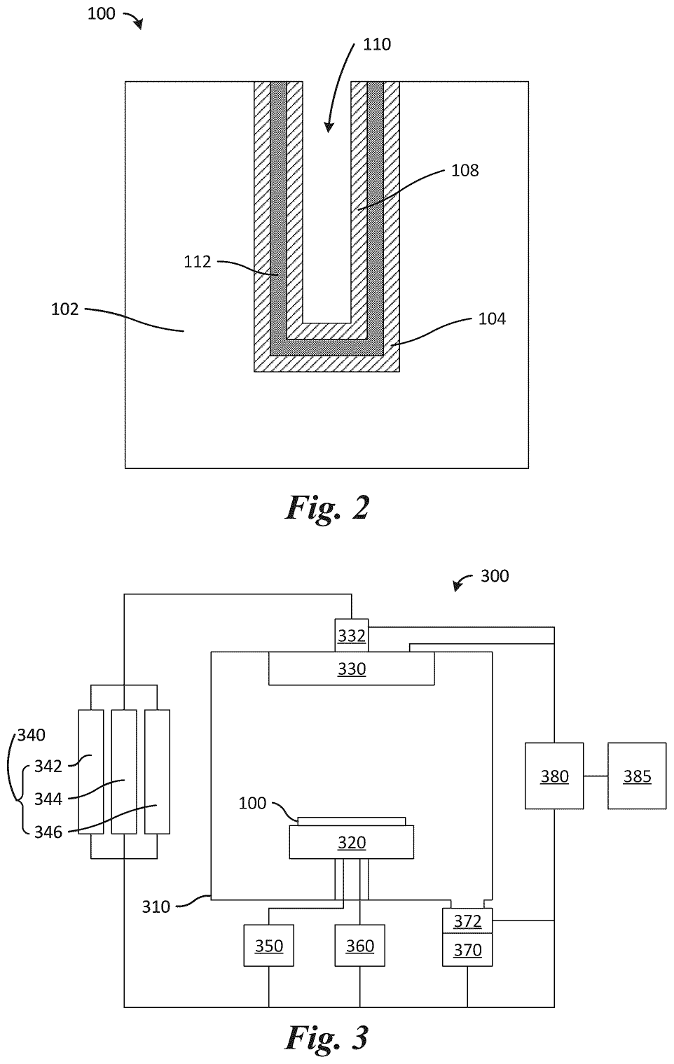

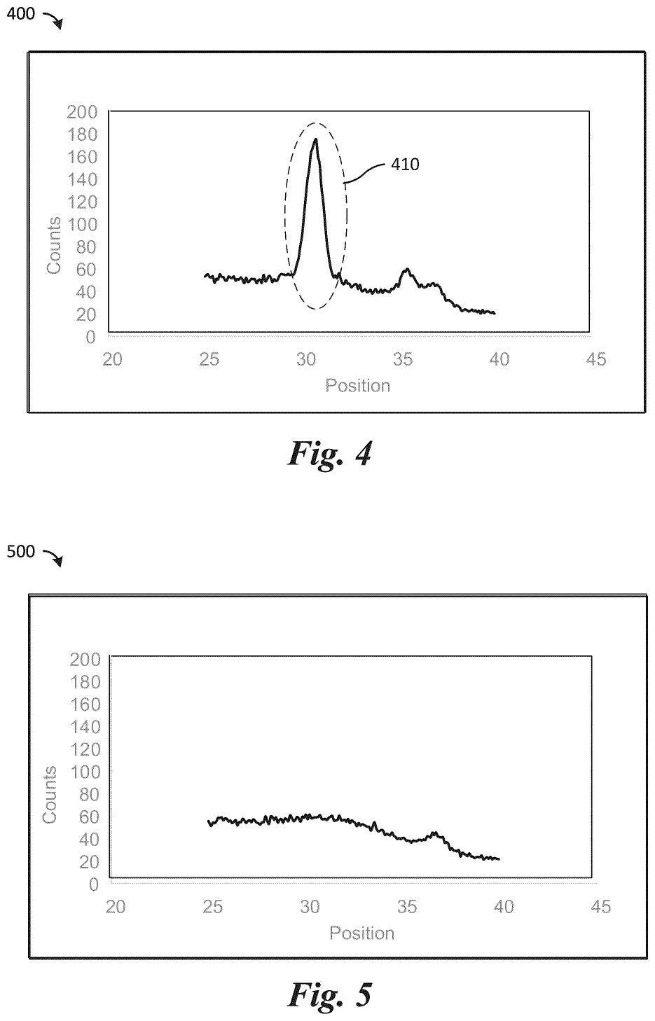

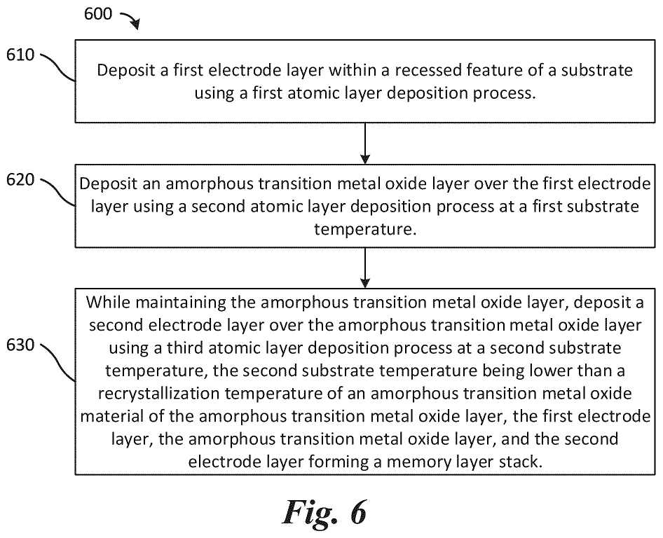

Embodiments provided below describe various methods, and systems of forming a memory device, and in particular, to methods, and systems that use atomic layer deposition at low temperatures to form a memory device in high aspect ratio features. The following description describes the embodiments. FIGS. 1A-1D are used to describe various steps of forming a memory device in a high aspect ratio feature on an example substrate. FIG. 2 is used to describe an annealing step which may be performed after the method described using FIGS. 1A-1D. An example atomic layer deposition system which may be used to perform the steps described using FIGS. 1A-1D is illustrated in FIG. 3. An X-ray diffraction (XRD) plot illustrating the premature crystallization of a hafnium zirconium oxide (HZO) layer deposited using an ALD process with a substrate temperature of 430° C. is described using FIG. 4. An XRD plot illustrating an HZO layer maintaining an amorphous state using an ALD process with a substrate temperature of 330° C. is described using FIG. 5. And FIGS. 6-8 are flowcharts used to describe three other example embodiment methods of forming a memory device within a high aspect ratio feature of this disclosure.

FIGS. 1A-1D illustrate cross-sectional views of a structure 100 through various steps of the method for forming a memory device in a high aspect ratio (HAR) feature of this disclosure. The various illustrations of the structure 100 only show a portion of a substrate to emphasize the method of this disclosure. However, the method of this disclosure may be applied over an entire substrate or wafer, such as over an entire substrate comprising many HAR features. And the method of this disclosure may begin after receiving a substrate comprising a pre-formed HAR feature (or opening), such as the structure 100 illustrated in FIG. 1A.

FIG. 1A illustrates the structure 100 after an etching process formed a recessed feature 110 in a substrate portion 102 of the structure 100. The recessed feature 110 may be formed through any suitable etching process known in the art for forming HAR features, and the recessed feature 110 may be a HAR feature (or opening). For example, the recessed feature 110 may be a trench or a hole. In various embodiments, the recessed feature 110 is a part of a three-dimensional structure within the substrate portion 102.

The structure 100 comprises the substrate portion 102 with the recessed feature 110. The substrate portion 102 may be various materials suitable for semiconductor device fabrication, such as silicon, silicon-on-insulator (SOI), germanium, III-V compound semiconductors, or other appropriate substrates. In some embodiments, the substrate portion 102 may be a bulk semiconductor substrate, while in others, it may be a layer within a more complex stack of materials.

The recessed feature 110 is formed within the substrate portion 102 and serves as the foundation for the memory device. This recessed feature 110 may take various forms depending on the specific device architecture. In some embodiments, the recessed feature 110 may be a trench with vertical or sloped sidewalls. In other embodiments, the recessed feature 110 may be a cylindrical hole or a more complex three-dimensional structure.

In various embodiments, the recessed feature 110 has a high aspect ratio. The aspect ratio of the recessed feature 110 may vary depending on the specific device being fabricated. In some embodiments, the aspect ratio may be greater than 5:1, while in more aggressive designs, it could exceed 20:1 or even 50:1. In various embodiments, the recessed feature 110 may comprise a high aspect ratio between about 40:1 and 10:1.

Dimensions of the recessed feature 110 may vary widely based on the intended application and the level of device scaling. In some embodiments, a critical dimension (CD) of the recessed feature 110 may range from a few nanometers to several hundred nanometers. A depth of the recessed feature 110 may range from tens of nanometers to several micrometers, depending on a desired capacitance and other device parameters.

In various embodiments, sidewalls and a bottom of the recessed feature 110 may be treated or modified prior to subsequent deposition steps. For example, they may undergo cleaning processes, surface treatments to enhance adhesion, or the formation of additional layers not shown in FIG. 1A.

Still referring to FIG. 1A, the structure 100 at this stage serves as the starting point for subsequent deposition steps that will form the memory device within the recessed feature 110. Atomic layer deposition (ALD) processes may be used on the structure 100 of FIG. 1A to deposit various layers of the memory device within the recessed feature 110 such that the various layers are uniform and conformal, such as a first ALD process described using FIG. 1B.

FIG. 1B illustrates the structure 100 after performing a first ALD process to deposit a first material within the recessed feature 110 to form a first electrode layer 104. The first ALD process may be a conventional ALD process suitable for forming the first electrode layer within the recessed feature 110. For example, the first ALD process may comprise a first precursor gas exposure which adsorbs onto the surface of the structure 100. The first ALD process may then use a first purge gas to purge excess first precursor gas and any byproducts, where the first purge gas is an inert gas. After, the first ALD process may then expose the structure 100 to a first reactant gas to react with the adsorbed first precursor gas to form a first monolayer of desired material to form the first electrode layer 104. Subsequent steps comprise performing another purge step and then repeating the steps described above until a desired thickness for the deposited layer is achieved. Conventional temperatures for the structure 100 may be used during the first ALD process.

The first electrode layer 104 is deposited using the first atomic layer deposition (ALD) process described above, which enables conformal coverage along the sidewalls and bottom of the high aspect ratio recessed feature 110. This conformal coverage is beneficial for ensuring uniform electrical characteristics throughout the device.

In various embodiments, the first electrode layer 104 may comprise a conductive material suitable for use as an electrode in memory devices. Potential materials for the first electrode layer 104 comprise titanium nitride, tantalum nitride, tungsten, ruthenium, or other transition metals and their compounds. The specific material choice depends on factors such as electrical conductivity, work function, and compatibility with subsequent processing steps.

The thickness of the first electrode layer 104 is precisely controlled by the first ALD process. Typical thicknesses may range from 2 to 20 nanometers, though thicker or thinner layers may be employed depending on the specific device specifications. Further, the number of cycles of the first ALD process through the first precursor gas, the first reactant gas, and the first purge gas determines the thickness of the first electrode layer 104. The ability to deposit conformal, ultra-thin layers with high uniformity within the recessed feature 110 is an advantage of the ALD technique in this disclosure.

The deposition of the first electrode layer 104 occurs at a controlled temperature, selected to optimize film properties while maintaining compatibility with the substrate and subsequent processing steps. This temperature may typically range from 200° C. to 500° C., though lower or higher temperatures may be used in some embodiments.

The first ALD process for depositing the first electrode layer 104 involves alternating pulses of precursor gases and reactant gases, with purge steps between each pulse. For example, in the case of titanium nitride, the process might alternate between a titanium-containing precursor and a nitrogen-containing reactant. The specific precursors, pulse times, and purge times may be optimized to achieve the desired film properties and deposition rate. Further, the first ALD process ensures that the layer thickness remains consistent from the top to the bottom of the recessed feature 110, avoiding potential difficulties such as pinch-off or void formation that can occur with other deposition techniques.

In various embodiments, the first precursor gas of the first ALD process may comprise TiCl₄, or tetrakis(dimethylamino) titanium (TDMAT). In similar embodiments, the first reactant gas may comprise NH₃ (or a deuterated version ND₃), or N₂H₄. And the first purge gas may be a suitable inert gas such as argon (Ar), or nitrogen (N₂).

By utilizing the first ALD process for the deposition of the first electrode layer 104, the method establishes a foundation for the subsequent layers of the memory device, ensuring excellent coverage and precise thickness control within the challenging geometry of the high aspect ratio recessed feature 110.

FIG. 1C illustrates the structure 100 after depositing a suitable material within the recessed feature 110 over the first electrode layer 104 to form an amorphous transition metal oxide layer 106.

The amorphous transition metal oxide layer 106 is deposited using a second ALD process at a first substrate temperature. The first substrate temperature is selected to be sufficiently low to prevent crystallization of the transition metal oxide material. The first substrate temperature ensuring the amorphous transition metal oxide layer 106 remains in an amorphous state.

Various transition metal oxides may be employed for the amorphous transition metal oxide layer 106, each offering distinct properties suitable for different memory applications. In various embodiments, the amorphous transition metal oxide layer 106 comprises hafnium oxide (HfO₂), zirconium oxide (ZrO₂), hafnium zirconium oxide (HfZrO₂), titanium oxide (TiO₂), tantalum oxide (Ta₂O₅), and niobium oxide (Nb₂O₅). The composition of the amorphous transition metal oxide layer 106 may be tailored by adjusting the ratios of different precursors during the second ALD process. For instance, in the case of hafnium zirconium oxide, the ratio of hafnium to zirconium may be precisely controlled to optimize the electrical properties of the resulting amorphous transition metal oxide layer 106. In other embodiments, the amorphous transition metal oxide layer 106 comprises a high-k oxide such as HfZrO, or HfZrO doped with La, Nb, or etcetera.

In various embodiments, the thickness of the amorphous transition metal oxide layer 106 may range from 3 to 15 nanometers, though thicker or thinner layers may be employed depending on the specific device specifications and desired electrical properties of the memory device being fabricated, such as capacitance.

The first substrate temperature for depositing the amorphous transition metal oxide layer 106 is determined for maintaining the amorphous state. In various embodiments, the first substrate temperature may be between 300° C. and 350° C., with the exact value depending on the specific material and desired properties of the structure 100. For example, in an embodiment where the amorphous transition metal oxide layer is amorphous hafnium zirconium oxide, the first substrate temperature may be 330° C.

The second ALD process for the amorphous transition metal oxide layer 106 involves alternating pulses of metal precursors and oxygen-containing reactants, with purge steps between each pulse. The difference between the second ALD process and the first ALD process are the precursor gases, reactant gases, and the temperature maintained during the corresponding ALD process. For example, the deposition of hafnium oxide may alternate between a hafnium-containing precursor (such as tetrakis(ethylmethylamino) hafnium) and an oxygen-containing reactant (such as water or ozone).

As an example, the second ALD process may perform the same steps as described for the first ALD process, but using a second precursor gas, a second reactant gas, and a second purge gas. Further, the second ALD process is performed at the first substrate temperature below the amorphous-to-crystalline temperature (or recrystallization temperature) of the amorphous transition metal oxide material of the amorphous transition metal oxide layer 106.

In various embodiments, the second precursor gas of the second ALD process may comprise metal organics such as tetrakis(ethylmethylamino) hafnium (TEMAHf), or tetrakis(ethylmethylamino) zirconium (TEMAZr), or tris(dimethylamido) cyclopentadienyl hafnium (Hy-ALD), or tris(dimethylamino) cyclopentadienyl zirconium (Zy-ALD). In similar embodiments, the second reactant gas may comprise oxidants, such as ozone, water, deuterated water (D₂O), or oxygen. And the second purge gas may be as described for the first purge gas above, such as any suitable inert gas.

Maintaining the amorphous state of the amorphous transition metal oxide layer 106 at this stage may be used to form memory devices with improved ferroelectric or anti-ferroelectric properties through a subsequent controlled crystallization process. The amorphous structure allows for greater flexibility in manipulating the final crystalline phase, which directly influences the electrical properties of the memory device.

The conformal nature of the second ALD process ensures that the amorphous transition metal oxide layer 106 maintains a consistent thickness throughout the high aspect ratio recessed feature 110, which enables uniform device performance across the entire structure 100.

FIG. 1D illustrates the structure 100 after depositing, at a second substrate temperature, another suitable material within the recessed feature 110 and over the amorphous transition metal oxide layer 106 to form a second electrode layer 108. In various embodiments, the second electrode layer 108 may serve as a capping layer for the memory device being formed in the recessed feature 110.

The second electrode layer 108 is deposited using a third atomic layer deposition (ALD) process at a second substrate temperature. The second substrate temperature is carefully selected to be low enough to prevent crystallization of the underlying amorphous transition metal oxide layer 106. And the third ALD process may perform the same ALD steps described for the first ALD process or the second ALD process, but using a second substrate temperature, a third precursor gas, a third reactant gas, and a third purge gas suitable for the material of the second electrode layer 108.

The second electrode layer 108 may comprise various conductive materials suitable for use as a top electrode (or capping layer) in memory devices. Potential materials may comprise titanium nitride (TiN), tantalum nitride (TaN), tungsten (W), ruthenium (Ru), platinum (Pt), iridium (Ir), and conductive metal oxides (e.g., indium tin oxide). The choice of material for the second electrode layer 108 depends on factors such as work function, compatibility with the underlying transition metal oxide, and subsequent processing specifications.

The thickness of the second electrode layer 108 typically ranges from 2 to 20 nanometers, though this may vary based on specific device designs and performance targets. Again, the thickness of the second electrode layer 108 may be determined by the number of cycles of the third ALD process.

The second substrate temperature for depositing the second electrode layer 108 is low enough to prevent crystallization of the amorphous transition metal oxide layer 106. It is generally maintained between 200° C. and 350° C., depending on the specific electrode material and the crystallization temperature of the underlying amorphous transition metal oxide layer 106. This temperature is kept sufficiently low to be beneath the amorphous-to-crystalline temperature (or recrystallization temperature) of the amorphous transition metal oxide layer 106.

The third ALD process for the second electrode layer 108 comprises alternating pulses of precursor gases, reactant gases, and a third purge gas specific to the chosen electrode material. For instance, in the case of titanium nitride, the process might alternate between a titanium-containing precursor (such as tetrakis(dimethylamino) titanium) and a nitrogen-containing reactant (such as ammonia). Again, the third ALD process may be as similarly described for the first and second ALD process, but using a second substrate temperature, a third precursor gas, a third reactant gas, and a third purge gas. In some embodiments, the third ALD process may be the same as the first ALD process, and both may use the second substrate temperature to deposit the first electrode layer 104 and the second electrode layer 108 of the same material.

In various embodiments, the third precursor gas of the third ALD process may comprise TiCl₄, or tetrakis(dimethylamino) titanium (TDMAT). In similar embodiments, the third reactant gas may comprise NH₃ (or a deuterated version ND₃), or N₂H₄. And the third purge gas may be as described for the first or second purge gas above, such as any suitable inert gas such as argon (Ar) or nitrogen (N₂).

In some embodiments, the second electrode layer 108 may be engineered to have a specific amount of oxygen. For example, when using titanium nitride, the process may be adjusted to incorporate approximately 18 to 22 atomic percent oxygen in the second electrode layer 108. This oxygen content may play a role in the subsequent crystallization of the amorphous transition metal oxide layer 106 and influence the final electrical properties of the device (or structure 100).

The conformal nature of the third ALD process ensures that the second electrode layer 108 maintains consistent thickness and composition throughout the high aspect ratio recessed feature 110. This uniformity also enables consistent electrical performance across the entire structure 100.

By depositing the second electrode layer 108 at a carefully controlled low temperature (the second substrate temperature), the method preserves the amorphous state of the underlying amorphous transition metal oxide layer 106, setting the stage for subsequent controlled crystallization steps that will define the final electrical characteristics of the memory device. In various embodiments, the first substrate temperature may be higher than the second substrate temperature. And in other embodiments, the first substrate temperature may be lower than the second substrate temperature. And in even further embodiments, the first substrate temperature may be the same as the second substrate temperature. The second substrate temperature is chosen such that the second electrode layer 108 does not cause a premature crystallization of the amorphous transition metal oxide layer 106.

The resulting structure 100 comprises a memory layer stack formed within the recessed feature 110. The memory layer stack comprises the first electrode layer 104, the amorphous transition metal oxide layer 106, and the second electrode layer 108. This memory layer stack forms the basis for a memory device, with the controlled deposition temperatures enabling precise management of the amorphous state of the amorphous transition metal oxide layer 106. The deposition processes described using FIGS. 1A-1E also deposits the layers over a top surface (or field area) surrounding the recessed feature 110. In various embodiments, after depositing the various layers and depositing the second electrode layer 108, a planarization process may be performed to remove material deposited over the top surface, such as a chemical mechanical planarization (CMP) process for example. Further, FIG. 1E may illustrate the structure 100 after depositing the second electrode layer 108 and performing a planarization process. In various embodiments, an annealing process may be performed after completing the deposition of the second electrode layer 108, such as described using FIG. 2 below.

FIG. 2 illustrates the structure 100 after an annealing process has been performed, transforming the previously amorphous transition metal oxide layer 106 into a crystalline transition metal oxide layer 112.

The annealing process is conducted at a third substrate temperature, which is higher than the second substrate temperature used for depositing the second electrode layer 108. This elevated temperature provides the recrystallization energy to induce crystallization in the amorphous transition metal oxide material.

The third substrate temperature typically ranges from 350° C. to 600° C., depending on the specific composition of the amorphous transition metal oxide and the desired crystalline phase. The duration of the annealing process may vary from a few seconds to several minutes, balancing the desire for complete crystallization with thermal budget considerations.

During the annealing process, the amorphous transition metal oxide layer 106 undergoes a phase transformation, forming a crystalline structure. The resulting crystalline transition metal oxide layer 112 may exhibit different crystalline phases depending on the annealing conditions and the composition of the original amorphous layer. And the oxygen content of the second electrode layer 108 may further aid in the formation of the desired crystalline phase of the crystalline transition metal oxide layer 112. For example, in the case of hafnium zirconium oxide, the crystalline phase may be ferroelectric or anti-ferroelectric, depending on the specific processing conditions and composition.

The crystallization process can significantly alter the electrical properties of the crystalline transition metal oxide layer 112. In the case of a ferroelectric phase, the material exhibits a spontaneous electric polarization that can be reversed by an applied electric field, forming the basis for non-volatile memory operation.

The controlled crystallization enabled by this method allows for precise engineering of the crystalline structure, which directly influences the memory device's performance characteristics such as polarization, coercive field, and retention. Further, the memory layer stack now comprises the first electrode layer 104, the crystalline transition metal oxide layer 112, and the second electrode layer 108. In various embodiments, the memory layer stack may be used to form a memory capacitor.

Additionally, the crystallization process may also affect the surrounding layers. For instance, oxygen from the transition metal oxide layer may diffuse into the adjacent electrode layers, particularly the second electrode layer 108. This oxygen diffusion can influence the electrical properties of the electrodes and the overall device performance.

The high aspect ratio of the recessed feature 110 presents challenges for uniform heat distribution during the annealing process. However, the conformal nature of the previously deposited layers helps ensure consistent crystallization throughout the structure 100, which is a benefit of the method of this disclosure over conventional methods of forming memory devices.

By carefully controlling the annealing conditions, this step completes the formation of the active memory element within the high aspect ratio structure, creating a functional device with the desired crystalline properties for memory applications. In various embodiments, after performing the annealing process described using FIG. 2, the recessed feature 110 may be overfilled with material, and a planarization process may be performed to remove excess material from the recessed feature 110. For example, a CMP process may be performed after the annealing to remove excess material from the recessed feature 110, and to prevent CMP residue from accumulating within the recessed feature 110. An atomic layer deposition (ALD) system 300 capable of depositing the various layers of the memory device formed in the recessed feature 110 of FIGS. 1A-1D is described using FIG. 3.

FIG. 3 depicts a schematic diagram of an ALD system 300 capable of implementing the method described in FIGS. 1A-1D for forming a memory device in a high aspect ratio structure.

The ALD system 300 comprises a processing chamber 310 that houses a substrate holder 320. The substrate holder 320 may be designed to accommodate various substrate sizes and may comprise heating elements for temperature control. In some embodiments, the substrate holder 320 may also have rotation capabilities to enhance deposition uniformity.

An upper assembly 330 is positioned above the substrate holder 320 and features a gas inlet 332 for introducing precursor and reactant gases into the chamber. The upper assembly 330 may be designed to promote uniform gas distribution across the substrate surface.

A gas system 340 is connected to the processing chamber 310, supplying the various gases for the ALD process, whether the first, second, or third ALD process. The gas system 340 provides a first processing gas 342, a second processing gas 344, and a carrier gas 346. These gases may be precisely controlled and introduced into the chamber as prescribed by a specific ALD recipe. For example, the first processing gas 342 may be the first, second, or third precursor gas in various embodiments. The second processing gas 344 may be the first, second, or third reactant gas in various embodiments. And the carrier gas 346 may be the first, second, or third purge gas in various embodiments. The gas system 340 may be designed for whichever of the first, second, or third ALD processes are being implemented in the processing chamber 310.

In some embodiments, the ALD system 300 may comprise multiple processing chambers 310 comprising similar elements, but used for the different ALD processes of this disclosure. For example, the ALD system 300 may comprise three processing chambers 310, where a first processing chamber may be used for the first ALD process, a second processing chamber may be used for the second ALD process, and a third processing chamber may be used for the third ALD process as described above.

When depositing the amorphous transition metal oxide layer 106, the first processing gas 342 might be a metal precursor like tetrakis(ethylmethylamino) hafnium for hafnium oxide, while the second processing gas 344 could be an oxygen source such as water or ozone.

The carrier gas 346 may be an inert gas like argon or nitrogen, used to purge the chamber between precursor pulses and to assist in precursor delivery.

A temperature control system 350 regulates the temperature within the processing chamber 310. This system may include heating elements, cooling systems, and temperature sensors to maintain precise temperature control during all stages of the deposition process. For example, the temperature control system 350 may be used to maintain the first substrate temperature or the second substrate temperature depending on the ALD process being performed in the processing chamber 310.

A substrate power source 360 is coupled to the substrate holder 320. This power source may be used for plasma-enhanced ALD processes or for substrate biasing to influence film properties.

For maintaining appropriate pressure levels, a vacuum pump 370 is connected to the processing chamber 310 via a valve 372. This configuration enables precise pressure control throughout the deposition process, typically maintaining pressures in the range of 0.1 to 10 Torr.

The ALD system 300 is managed by a controller 380, which coordinates the various components and process parameters. The controller 380 may be a microprocessor-based system capable of executing pre-programmed instructions.

The controller 380 is coupled to a memory 385, which stores process recipes, parameters, and control programs for executing the desired deposition sequences. The memory 385 may include various types of storage media, such as RAM, ROM, or magnetic or optical disks.

This ALD system 300 configuration enables the carefully controlled, layer-by-layer deposition desired for forming the memory device structures within high aspect ratio features. The ability to precisely manage gas flows, temperatures, and pressures is beneficial for maintaining the amorphous state of the transition metal oxide layer during initial deposition and allows for subsequent crystallization during the annealing process.

FIG. 4 presents a first plot 400 showing X-ray diffraction (XRD) results for a hafnium zirconium oxide (HZO) film deposited using an ALD process at a high temperature. This plot illustrates the undesired early crystallization of the HZO film during the ALD process, which may be emphasized by a peak 410 corresponding to the premature crystallization of the HZO layer.

The X-axis of the plot represents the diffraction angle (2θ), typically ranging from 20° to 45°. The Y-axis shows the intensity of the diffracted X-rays, measured in counts.

In the first plot 400, distinct peaks are visible at specific diffraction angles (such as the peak 410), indicating the presence of crystalline phases within the HZO film. These peaks correspond to various crystallographic planes of the HZO material. The presence of these peaks demonstrates that crystallization has occurred during the deposition process, rather than maintaining the desired amorphous state.

The early crystallization observed in the first plot 400 is undesirable for the method described in FIGS. 1A-1D, as it reduces control over the final crystalline structure and may lead to non-uniform electrical properties in the resulting memory device. As a result, the use of low temperature ALD process may prevent the premature crystallization of the transition metal oxide layers, which is illustrated in a second plot 500 of FIG. 5.

FIG. 5 displays a second plot 500 depicting XRD results for an HZO film deposited using the low-temperature ALD process described in this disclosure (specifically, at 330° C.). This plot demonstrates the successful prevention of early crystallization in the HZO film.

The axes in FIG. 5 are identical to those in FIG. 4, allowing for direct comparison between the two results. In contrast to FIG. 4, the plot in FIG. 5 shows a broad, low-intensity feature without distinct peaks. This diffraction pattern is characteristic of an amorphous material, indicating that the HZO film has remained in a non-crystalline state following the low-temperature ALD process (such as the second ALD process described above).

The absence of sharp diffraction peaks in FIG. 5 confirms that the low-temperature deposition method has successfully prevented premature crystallization of the HZO film. This amorphous state is useful for the subsequent controlled crystallization step described in FIG. 2, allowing for precise engineering of the final crystalline structure and electrical properties of the memory device.

In both FIGS. 4 and 5, the HZO film represented corresponds to the amorphous transition metal oxide layer 106 described in FIGS. 1A-1D. These XRD results highlight the influence of temperature control during the ALD process to maintain the desired amorphous state of the transition metal oxide layer, which is a benefit of the disclosed method for forming memory devices in high aspect ratio structures of this disclosure. Other embodiment methods for forming a memory device in high aspect ratio features may be described using the flowcharts illustrated in FIGS. 6-8.

FIGS. 6-8 illustrate example methods of forming memory devices in high aspect ratio features in accordance with embodiments of this disclosure. The methods of FIGS. 6-8 may be combined with other methods and performed using the systems and apparatuses as described herein, such as the ALD system 300 illustrated in FIG. 3, and the methods described using FIGS. 1A-1D, and FIG. 2. Although shown in a logical order, the arrangement and numbering of the steps of FIGS. 6-8 are not intended to be limited. The method steps of FIGS. 6-8 may be performed in any suitable order.

Referring to FIG. 6, step 610 of a method 600 of forming a memory device in a high aspect ratio feature deposits a first electrode layer within a recessed feature of a substrate using a first atomic layer deposition process. The recessed feature may be the recessed feature 110 of FIG. 1A, and the first ALD process may be as described for FIG. 1B. Step 620 of the method 600 deposits an amorphous transition metal oxide layer over the first electrode layer using a second atomic layer deposition process at a first substrate temperature. The step 620 may be illustrated by the structure 100 in FIG. 1C, and the amorphous transition metal oxide layer may be the amorphous transition metal oxide layer 106 of FIG. 1C. Additionally, the second atomic layer deposition process may be the same as the second ALD process described above.

Still referring to FIG. 6, the step 630 of the method 600, while maintaining the amorphous transition metal oxide layer, deposits a second electrode layer over the amorphous transition metal oxide layer using a third atomic layer deposition process. The second substrate temperature being lower than a recrystallization temperature of an amorphous transition metal oxide material of the amorphous transition metal oxide layer. And the first electrode layer, the amorphous transition metal oxide layer, and the second electrode layer forming a memory layer stack. The second electrode layer may be as described for the second electrode layer 108 of FIG. 1D, and step 630 may be the step described using FIG. 1D. Similarly, the second substrate temperature may be as described above, and the third atomic layer deposition process may be the third ALD process described using FIG. 1D. In some embodiments, the method 600 may perform an annealing step after step 630, such as described using FIG. 2.

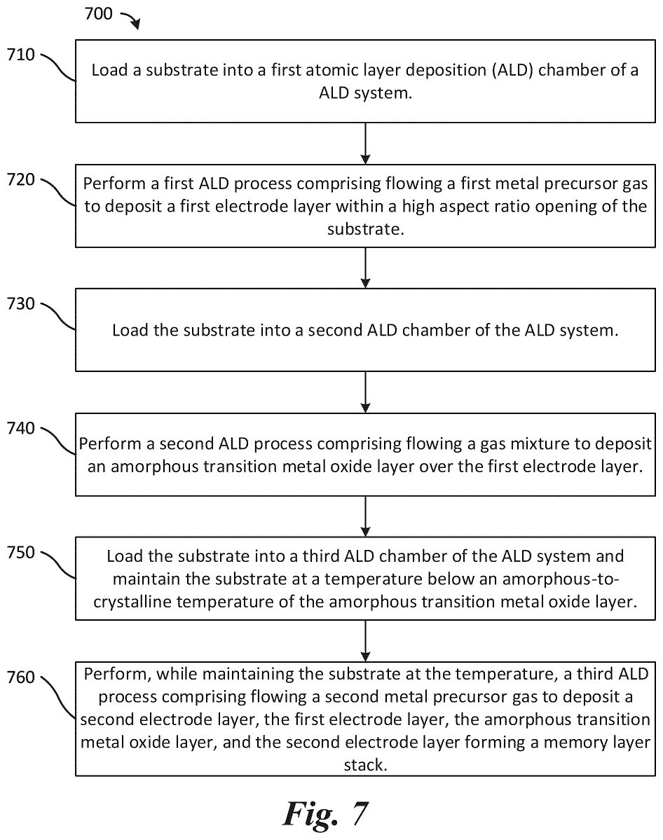

Now referring to FIG. 7, step 710 of a method 700 of forming a memory device in a high aspect ratio feature loads a substrate into a first atomic layer deposition (ALD) chamber of a ALD system. The substrate may be the structure 100 illustrated in FIG. 1A, and the ALD system may be the ALD system 300 described using FIG. 3. Step 720 performs a first ALD process comprising flowing a first metal precursor gas to deposit a first electrode layer within a high aspect ratio opening of the substrate. In an embodiment, step 720 may be the step described using FIG. 1B, and the first electrode layer may be the first electrode layer 104. Further, the first ALD process may be the first ALD process described using FIG. 1B, where the first metal precursor gas may be the first precursor gas. Additionally, the high aspect ratio opening may be the recessed feature 110 of FIG. 1B.

Step 730 of the method 700 loads the substrate into a second ALD chamber of the ALD system. And step 740 performs a second ALD process comprising flowing a gas mixture to deposit an amorphous transition metal oxide layer over the first electrode layer. The second ALD process may be as described above using FIG. 1C, and the amorphous transition metal oxide layer may be the amorphous transition metal oxide layer 106. The gas mixture may be either the second precursor gas or the second reactant gas. After, the method 700 proceeds to step 750.

Step 750 of the method 700 loads the substrate into a third ALD chamber of the ALD system and maintains the substrate at a temperature below an amorphous-to-crystalline temperature of the amorphous transition metal oxide layer. And step 760 performs, while maintaining the substrate at the temperature, a third ALD process comprising flowing a second metal precursor gas to deposit a second electrode layer. The first electrode layer, the amorphous transition metal oxide layer, and the second electrode layer forming a memory layer stack. Again, the second ALD process may be as described using FIG. 1C, and the third ALD process may be as described using FIG. 1D. The ALD system 300 of FIG. 3 may comprise three processing chambers which may be used as the first ALD chamber, the second ALD chamber, and the third ALD chamber specified in steps 710, 730, and 750.

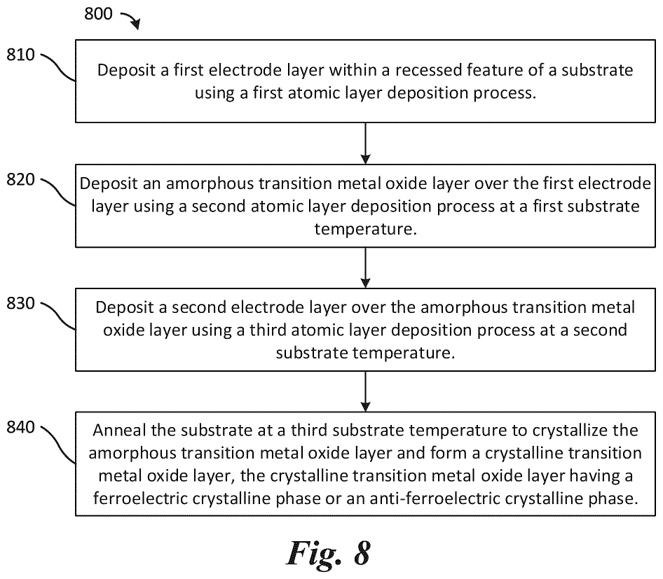

Now referring to FIG. 8, a method 800 for forming a memory device in a high aspect ratio feature deposits a first electrode layer within a recessed feature of a substrate using a first atomic layer deposition process in step 810. Step 810 may be as described using FIG. 1B, and be performed similarly to as described for step 610 of the method 600. Further, the recessed feature of step 810 may be the recessed feature 110 illustrated in FIG. 1B.

In step 820, the method 800 deposits an amorphous transition metal oxide layer over the first electrode layer using a second atomic layer deposition process at a first substrate temperature. Again, step 820 may be as described using FIG. 1C and step 620 of the method 600 in FIG. 6. Step 830 of the method 800 deposits a second electrode layer over the amorphous transition metal oxide layer using a third atomic layer deposition process at a second substrate temperature. The step 830 may be illustrated for the structure 100 in FIG. 1D.

Still referring to FIG. 8, the method 800 anneals the substrate at a third substrate temperature to crystallize the amorphous transition metal oxide layer and form a crystalline transition metal oxide layer in step 840. The crystalline transition metal oxide layer having a ferroelectric crystalline phase or an anti-ferroelectric crystalline phase. The difference between the method 600 of FIG. 6 and the method 800 of FIG. 8, is the annealing step 840 of FIG. 8. The first ALD process, the second ALD process, and the third ALD process may be as described above using FIGS. 1A-1D.

Example embodiments of the invention are described below. Other embodiments can also be understood from the entirety of the specification as well as the claims filed herein.

Example 1. A method of forming a memory device on a substrate includes depositing a first electrode layer within a recessed feature of the substrate using a first atomic layer deposition process, and depositing an amorphous transition metal oxide layer over the first electrode layer using a second atomic layer deposition process at a first substrate temperature. And the method further includes, while maintaining an amorphous state of the amorphous transition metal oxide layer, depositing a second electrode layer over the amorphous transition metal oxide layer using a third atomic layer deposition process at a second substrate temperature, the second substrate temperature being lower than a recrystallization temperature of an amorphous transition metal oxide material of the amorphous transition metal oxide layer, and the first electrode layer, the amorphous transition metal oxide layer, and the second electrode layer forming a memory layer stack.

Example 2. The method of example 1, where the amorphous transition metal oxide layer includes hafnium oxide, zirconium oxide, or hafnium zirconium oxide.

Example 3. The method of one of examples 1 or 2, where the first electrode layer includes a transition metal nitride, and the second electrode layer includes a transition metal nitride.

Example 4. The method of one of examples 1 to 3, where the first electrode layer and the second electrode layer include titanium nitride.

Example 5. The method of one of examples 1 to 4, where the first substrate temperature and the second substrate temperature are between 300° C. and 350° C., and where the first substrate temperature is greater than the second substrate temperature.

Example 6. The method of one of examples 1 to 5, where the recessed feature has a high aspect ratio between 40:1 and 10:1.

Example 7. The method of one of examples 1 to 6, where the first atomic layer deposition process is a cyclic process. One cycle of the cyclic process including flowing a first precursor gas to adsorb within the recessed feature, flowing a first purge gas to purge remaining first precursor gas and precursor reactants, flowing a first reactant gas to react within the recessed feature and form a first monolayer, and flowing the first purge gas to purge remaining first reactant gas and reactants.

Example 8. The method of one of examples 1 to 7, where the second atomic layer deposition process is performed at the first substrate temperature and is a cyclic process. One cycle of the cyclic process including flowing a second precursor gas to adsorb within the recessed feature, flowing a second purge gas to purge remaining second precursor gas and precursor reactants, flowing a second reactant gas to react within the recessed feature and form a second monolayer, and flowing the second purge gas to purge remaining second reactant gas and reactants.

Example 9. The method of one of examples 1 to 8, where the third atomic layer deposition process is performed at the second substrate temperature and is a cyclic process. One cycle of the cyclic process including flowing a third precursor gas to adsorb within the recessed feature, flowing a third purge gas to purge remaining third precursor gas and precursor reactants, flowing a third reactant gas to react within the recessed feature and form a third monolayer, and flowing the third purge gas to purge remaining third reactant gas and reactants.

Example 10. The method of one of examples 1 to 9, further including annealing the memory layer stack at a third substrate temperature to crystallize the amorphous transition metal oxide layer and form a crystalline transition metal oxide layer, the third substrate temperature being greater than the second substrate temperature.

Example 11. The method of one of examples 1 to 10, where the first electrode layer, the crystalline transition metal oxide layer, and the second electrode layer form a memory capacitor.

Example 12. The method of one of examples 1 to 11, where the crystalline transition metal oxide layer includes a ferroelectric crystalline phase or an anti-ferroelectric crystalline phase.

Example 13. The method of one of examples 1 to 12, where the second electrode layer is between 18 to 22 atomic percent oxygen.

Example 14. A method of forming a memory device on a substrate includes loading the substrate into a first atomic layer deposition (ALD) chamber of a ALD system, and performing a first ALD process including flowing a first metal precursor gas to deposit a first electrode layer within a high aspect ratio opening of the substrate. The method further includes loading the substrate into a second ALD chamber of the ALD system, and performing a second ALD process including flowing a gas mixture including tetrakis(ethylmethylamino) hafnium (TEMAHf), tetrakis(ethylmethylamino) zirconium (TEMAZr), and oxidants to deposit an amorphous transition metal oxide layer over the first electrode layer. And the method further includes loading the substrate into a third atomic layer deposition (ALD) chamber of the ALD system and maintaining the substrate at a temperature below an amorphous-to-crystalline temperature of the amorphous transition metal oxide layer, and performing, while maintaining the substrate at the temperature, a third ALD process including flowing a second metal precursor gas to deposit a second electrode layer, the first electrode layer, the amorphous transition metal oxide layer, and the second electrode layer forming a memory layer stack.

Example 15. The method of example 14, where the flowing of the gas mixture for the second ALD process includes flowing the TEMAHf and TEMAZr followed by flowing the oxidants.

Example 16. The method of one of examples 14 or 15, further including annealing the memory layer stack at a substrate temperature to crystallize the amorphous transition metal oxide layer and form a crystalline transition metal oxide layer, the crystalline transition metal oxide layer having a ferroelectric crystalline phase or an anti-ferroelectric crystalline phase, the substrate temperature being greater than the amorphous-to-crystalline temperature of the amorphous transition metal oxide layer, and where the second electrode layer is between 18 to 22 atomic percent oxygen after the annealing.

Example 17. A method of forming a memory device on a substrate includes depositing a first electrode layer within a recessed feature of the substrate using a first atomic layer deposition process, and depositing an amorphous transition metal oxide layer over the first electrode layer using a second atomic layer deposition process at a first substrate temperature. The method further includes depositing a second electrode layer over the amorphous transition metal oxide layer using a third atomic layer deposition process at a second substrate temperature. And the method further includes annealing the substrate at a third substrate temperature to crystallize the amorphous transition metal oxide layer and form a crystalline transition metal oxide layer, the crystalline transition metal oxide layer having a ferroelectric crystalline phase or an anti-ferroelectric crystalline phase.

Example 18. The method of example 17, where the annealing diffuses oxygen from the amorphous transition metal oxide layer into the second electrode layer such that the second electrode layer is between 18 to 22 atomic percent oxygen.

Example 19. The method of one of examples 17 or 18, where the first substrate temperature and the second substrate temperature are between 300° C. and 350° C.

Example 20. The method of one of examples 17 to 19, where the first electrode layer includes titanium nitride, the amorphous transition metal oxide layer includes hafnium zirconium oxide, the second electrode layer includes titanium nitride, and the crystalline transition metal oxide layer includes crystalline hafnium zirconium oxide.

Example 21. The method of one of examples 17 to 20, where the first electrode layer is deposited at the second substrate temperature.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming a memory device on a substrate, the method comprising:
depositing a first electrode layer within a recessed feature of the substrate using a first atomic layer deposition process;
depositing an amorphous transition metal oxide layer over the first electrode layer using a second atomic layer deposition process at a first substrate temperature; and
while maintaining an amorphous state of the amorphous transition metal oxide layer, depositing a second electrode layer over the amorphous transition metal oxide layer using a third atomic layer deposition process at a second substrate temperature, the second substrate temperature being lower than a recrystallization temperature of an amorphous transition metal oxide material of the amorphous transition metal oxide layer, the first electrode layer, the amorphous transition metal oxide layer, and the second electrode layer forming a memory layer stack.

2. The method of claim 1, wherein the amorphous transition metal oxide layer comprises hafnium oxide, zirconium oxide, or hafnium zirconium oxide.

3. The method of claim 1, wherein the first electrode layer comprises a transition metal nitride, and the second electrode layer comprises a transition metal nitride.

4. The method of claim 1, wherein the first electrode layer and the second electrode layer comprise titanium nitride.

5. The method of claim 1, wherein the first substrate temperature and the second substrate temperature are between 300° C. and 350° C., and wherein the first substrate temperature is greater than the second substrate temperature.

6. The method of claim 1, wherein the recessed feature has a high aspect ratio between 40:1 and 10:1.

7. The method of claim 1, wherein the first atomic layer deposition process is a cyclic process, one cycle of the cyclic process comprising:
flowing a first precursor gas to adsorb within the recessed feature;
flowing a first purge gas to purge remaining first precursor gas and precursor reactants;
flowing a first reactant gas to react within the recessed feature and form a first monolayer; and
flowing the first purge gas to purge remaining first reactant gas and reactants.

8. The method of claim 1, wherein the second atomic layer deposition process is performed at the first substrate temperature and is a cyclic process, one cycle of the cyclic process comprising:
flowing a second precursor gas to adsorb within the recessed feature;
flowing a second purge gas to purge remaining second precursor gas and precursor reactants;
flowing a second reactant gas to react within the recessed feature and form a second monolayer; and
flowing the second purge gas to purge remaining second reactant gas and reactants.

9. The method of claim 1, wherein the third atomic layer deposition process is performed at the second substrate temperature and is a cyclic process, one cycle of the cyclic process comprising:
flowing a third precursor gas to adsorb within the recessed feature;
flowing a third purge gas to purge remaining third precursor gas and precursor reactants;
flowing a third reactant gas to react within the recessed feature and form a third monolayer; and
flowing the third purge gas to purge remaining third reactant gas and reactants.

10. The method of claim 1, further comprising:
annealing the memory layer stack at a third substrate temperature to crystallize the amorphous transition metal oxide layer and form a crystalline transition metal oxide layer, the third substrate temperature being greater than the second substrate temperature.

11. The method of claim 10, wherein the first electrode layer, the crystalline transition metal oxide layer, and the second electrode layer form a memory capacitor.

12. The method of claim 10, wherein the crystalline transition metal oxide layer comprises a ferroelectric crystalline phase or an anti-ferroelectric crystalline phase.

13. The method of claim 10, wherein the second electrode layer is between 18 to 22 atomic percent oxygen.

14. A method of forming a memory device on a substrate, the method comprising:
loading the substrate into a first atomic layer deposition (ALD) chamber of a ALD system;
performing a first ALD process comprising flowing a first metal precursor gas to deposit a first electrode layer within a high aspect ratio opening of the substrate;
loading the substrate into a second ALD chamber of the ALD system;
performing a second ALD process comprising flowing a gas mixture comprising tetrakis(ethylmethylamino) hafnium (TEMAHf), tetrakis(ethylmethylamino) zirconium (TEMAZr), and oxidants to deposit an amorphous transition metal oxide layer over the first electrode layer;
loading the substrate into a third atomic layer deposition (ALD) chamber of the ALD system and maintaining the substrate at a temperature below an amorphous-to-crystalline temperature of the amorphous transition metal oxide layer; and
performing, while maintaining the substrate at the temperature, a third ALD process comprising flowing a second metal precursor gas to deposit a second electrode layer, the first electrode layer, the amorphous transition metal oxide layer, and the second electrode layer forming a memory layer stack.

15. The method of claim 14, wherein the flowing of the gas mixture for the second ALD process comprises flowing the TEMAHf and TEMAZr followed by flowing the oxidants.

16. The method of claim 14, further comprising:
annealing the memory layer stack at a substrate temperature to crystallize the amorphous transition metal oxide layer and form a crystalline transition metal oxide layer, the crystalline transition metal oxide layer having a ferroelectric crystalline phase or an anti-ferroelectric crystalline phase, the substrate temperature being greater than the amorphous-to-crystalline temperature of the amorphous transition metal oxide layer, and wherein the second electrode layer is between 18 to 22 atomic percent oxygen after the annealing.

17. A method of forming a memory device on a substrate, the method comprising:
depositing a first electrode layer within a recessed feature of the substrate using a first atomic layer deposition process;
depositing an amorphous transition metal oxide layer over the first electrode layer using a second atomic layer deposition process at a first substrate temperature;
depositing a second electrode layer over the amorphous transition metal oxide layer using a third atomic layer deposition process at a second substrate temperature; and
annealing the substrate at a third substrate temperature to crystallize the amorphous transition metal oxide layer and form a crystalline transition metal oxide layer, the crystalline transition metal oxide layer having a ferroelectric crystalline phase or an anti-ferroelectric crystalline phase.

18. The method of claim 17, wherein the annealing diffuses oxygen from the amorphous transition metal oxide layer into the second electrode layer such that the second electrode layer is between 18 to 22 atomic percent oxygen.

19. The method of claim 17, wherein the first substrate temperature and the second substrate temperature are between 300° C. and 350° C.

20. The method of claim 17, wherein the first electrode layer comprises titanium nitride, the amorphous transition metal oxide layer comprises hafnium zirconium oxide, the second electrode layer comprises titanium nitride, and the crystalline transition metal oxide layer comprises crystalline hafnium zirconium oxide.
